(19) United States
(12) Patent Application Publication
(10) Pub. No.: US 2010/0100797 A1
(43) Pub. Date: Apr. 22, 2010

(54) DUAL MODE ERROR CORRECTION CODE (ECC) APPARATUS FOR FLASH MEMORY AND METHOD THEREOF

(75) Inventor: Ju-peng Chen, Taipei City (TW)

Correspondence Address: KIRTON AND MCCONKIE, 60 EAST SOUTH TEMPLE,, SUITE 1800, SALT LAKE CITY, UT, 84111, US

(73) Assignee: GENESYS LOGIC, INC., Shindian City (TW)

(21) Appl. No.: 12/252,454

(22) Filed: Oct. 16, 2008

(51) Int. Cl. H03M 13/15; G06F 11/10

(52) U.S. Cl. 714/785; 714/E11.032

(57) ABSTRACT

A dual mode error correction code (ECC) apparatus for the flash memory and method thereof are described. The dual mode error correction code (ECC) apparatus includes a syndrome detection unit, a first ECC unit, a second ECC unit, a switch module, and an interface module. The syndrome detection unit detects the data content for computing the amount of errors in the data content to determine whether the amount of the errors exceeds a pre-determined threshold value. The first ECC unit corrects the errors in the data content based on a first coding mode. The second ECC unit corrects the errors in the data content based on a second coding mode. The switch module either switches to the first ECC unit for activating the first coding mode of the first ECC unit if the amount of the errors is fewer than a pre-determined threshold value or switches to the second ECC unit for activating the second coding mode of the second ECC unit if the amount of the errors is greater than the pre-determined threshold value.

### FIELD OF THE INVENTION

The present invention relates to a memory apparatus and method thereof, and more particularly relates to a dual mode error correction code (ECC) apparatus for a flash memory controller and method thereof.

### BACKGROUND OF THE INVENTION

With the rapid development of semiconductor process technology, the geometry of memory has shrunk. Flash memory is a non-volatile memory that can retain the data stored therein even after power is removed. NAND flash, which is one type of flash memory, is a high-density memory design and has certain advantages over other types of memory. Taking an example of flash memory, the control of the flash memory needs to be upgraded for improving the reliability. The error correction code (ECC) is a common function in NAND (Not AND) flash memory controller for advanced process flash memory. However, the errors emerge speedily due to the advanced semiconductor processes. Therefore, the ECC requirement is increased and thus the manufacturing cost of the flash memory implementing ECC mechanism is considerably enlarged. Consequently, there is a need to develop a novel flash memory to solve the aforementioned problems.

### SUMMARY OF THE INVENTION

The objective of the present invention is to provide a dual mode error correction code (ECC) apparatus and method thereof to improve the flash memory controller.

According to the above objective, the present invention sets forth a dual mode error correction code (ECC) apparatus for a flash memory controller and method thereof. The dual mode error correction code (ECC) apparatus includes a syndrome detection unit, a first ECC unit, a second ECC unit, a switch module, and an interface module. The syndrome detection unit receives data content from the flash memory and detects the data content for computing the amount of the errors in the data content to determine whether the amount of the errors exceeds a pre-determined threshold value. The first ECC unit selectively corrects the errors in the data content based on a first coding mode. The second ECC unit selectively corrects the errors in the data content based on a second coding mode. The switch module switches to the first ECC unit for activating the first coding mode of the first ECC unit if the amount of the errors is fewer than a pre-determined threshold value or switches to the second ECC unit for activating the second coding mode of the second ECC unit if the amount of the errors is greater than the pre-determined threshold value.

The method of performing the dual mode error correction code (ECC) apparatus includes the steps of: (1) receiving data content from the flash memory; (2) detecting the data content for computing the amount of errors in the data content to determine whether the amount of the errors exceeds a pre-determined threshold value. If no, proceed to step steps (3a), (4a) and (5a). If yes, proceed to steps (3b), (4b) and (5b).

(3a) switching to a first coding mode of a first ECC unit for activating the first coding mode; (5a) correcting the errors based on the first coding mode if the amount of the errors is fewer than a pre-determined threshold value. In one embodiment, after the step (3a), the first decoding unit decodes the detected data content for locating the errors in step (4a).

(3b) switching to a second coding mode of a second ECC unit 104b for activating the second coding mode; (5b) correcting the errors based on the second coding mode if the amount of the errors is greater than the pre-determined threshold value. In one embodiment, after the step (3b), the second decoding unit decodes the detected data content for locating the errors in step (4b).

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic block diagram of a dual mode error correction code (ECC) apparatus according to one embodiment of the present invention; and

FIG. 2 is a flow chart of performing the dual mode error correction code (ECC) apparatus according to one embodiment of the present invention.

### DETAILED DESCRIPTION OF THE PREFERRED EMBODIMENTS

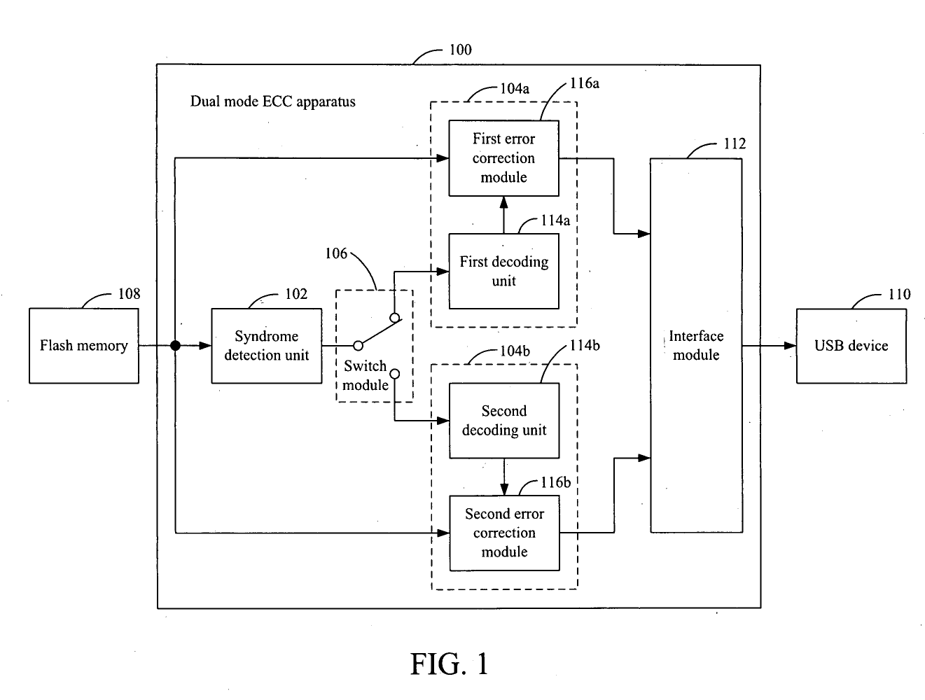

FIG. 1 is a schematic block diagram of a dual mode error correction code (ECC) apparatus 100 according to one embodiment of the present invention. The dual mode error correction code (ECC) apparatus 100 includes a syndrome detection unit 102, a first ECC unit 104a, a second ECC unit 104b, a switch module 106, and an interface module 112. The dual mode error correction code (ECC) apparatus 100 couples the flash memory 108 to a host 110 (e.g., USB device). The flash memory 108 couples to the syndrome detection unit 102, the first ECC unit 104a and the second ECC unit 104b, respectively, of the ECC apparatus 100. The switch module 106 couples the syndrome detection unit 102 to the first ECC unit 104a and the second ECC unit 104b, respectively. The first ECC unit 104a and the second ECC unit 104b, respectively, are coupled to the host 110 via an interface module 112.

The syndrome detection unit 102 receives data content from the flash memory and detects the data content for computing the amount of the errors in the data content to determine whether the amount of the errors exceeds a pre-determined threshold value. The switch module 106 switches to the first ECC unit for activating the first coding mode of the first ECC unit 104a if the amount of the errors is fewer than a pre-determined threshold value. The first ECC unit 104a then selectively corrects the errors in the data content based on a first coding mode. The switch module 106 switches to the second ECC unit for activating the second coding mode of the second ECC unit 104b if the amount of the errors is greater than the pre-determined threshold value. The second ECC unit 104b then selectively corrects the errors in the data content based on a second coding mode.

The first ECC unit 104a further comprises a first decoding unit 114a and a first error correction module 116a. The first decoding unit 114a coupled to the switch module 106 selectively decodes the detected data content from the syndrome detection unit 102 for locating the errors therein. The first error correction module 116a coupled to the first decoding unit 114a corrects the located errors in the decoded data content based on the first coding mode. For example, the first coding mode performed by the first decoding unit is Reed-Solomon (RS) structure algorithm.

The second ECC unit further comprises a second decoding unit 114b and a second error correction module 116b. The second decoding unit 114b selectively decodes the detected data content from the syndrome detection unit 102 for locating the errors therein. The second error correction module 116b coupled to the second decoding unit 114b corrects the located errors in the decoded data content based on the second coding mode. For example, the second coding mode performed by the second decoding unit is Bose, Ray-Chaudhuri and Hocquenghem (BCH) structure algorithm.

The time of locating the errors of the data content in the first error correction module 116a is greater than the time of locating the errors of the data content in the second error correction module 116b. That is, the correction time of the errors based on the first coding mode is shorter the correction time of the errors based on the second coding mode in view of the same amount of errors.

In one embodiment, the syndrome detection unit 102 is performed by either RS algorithm or BCH algorithm. In one embodiment, the detection time of the syndrome detection unit 102 based on the RS algorithm is shorter than the detection time of the syndrome detection unit 102 based on the BCH algorithm in view of the same amount of errors. A first correction unit of the first coding mode is different from a second correction unit of the second coding mode. For example, the first correction unit of the first coding mode is greater than the second correction unit of the second coding mode. In one embodiment, the characteristics of BCH algorithm and RS algorithm are described, respectively, in detail as follow:

(1) Binary BCH

This code operates on a block of binary bits. Its correction unit is bit. The code operates on a considerably lower number of bits with respect to the Reed-Solomon code. The canonical coding and decoding structures process the data block by means of sequential operations on the bits to be coded or decoded. The latency to code and decode data blocks is higher than the Reed-Solomon code latency since Reed-Solomon code operates on symbols.

(2) Reed Solomon

It operates on a block of symbols composed by a plurality of bits. Its correction unit is symbol. The canonical coding and decoding structures process the data block by means of sequential operations on the symbols to be coded or decoded. The latency to code and decode data blocks is lower than the BCH binary code latency since Reed Solomon operates on symbols rather than bits.

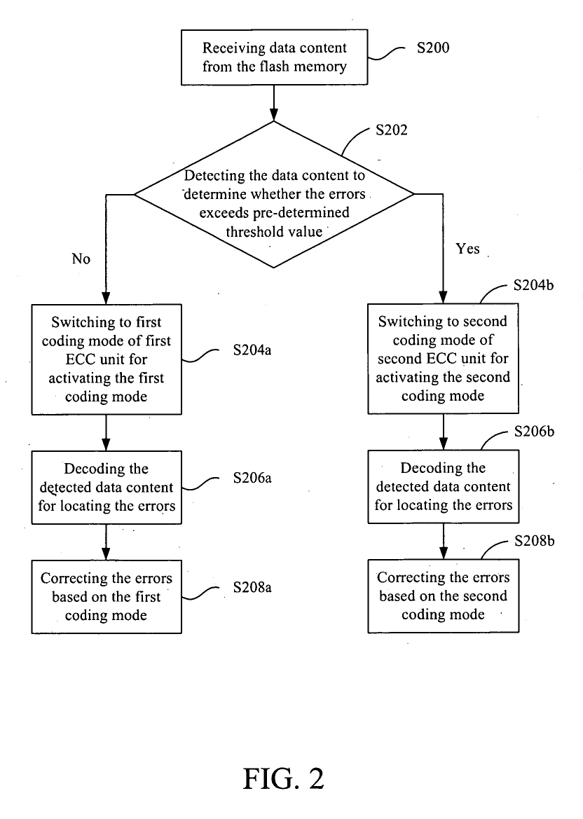

Please refer to FIG. 1 and FIG. 2. FIG. 2 is a flow chart of performing the dual mode error correction code (ECC) apparatus 100 according to one embodiment of the present invention. The method of performing the dual mode error correction code (ECC) apparatus includes the steps of:

In step S200, receiving data content from the flash memory.

In step S202, syndrome detection unit 102 detects the data content for computing the amount of errors in the data content to determine whether the amount of the errors exceeds a pre-determined threshold value. If no, proceed to step S204a, S206a and S208a. If yes, proceed to step S204b, S206b and S208b.

In step S204a, the switch module 106 switches to a first coding mode of a first ECC unit 104a for activating the first coding mode if the amount of the errors is fewer than a pre-determined threshold value. In one embodiment, after the step S204a, the first decoding unit 114a decodes the detected data content for locating the errors, as shown in step S206a. In step S208a, the first error correction module 116a corrects the errors based on the first coding mode.

In step S204b, the switch module 106 switches to a second coding mode of a second ECC unit 104b for activating the second coding mode if the amount of the errors is greater than the pre-determined threshold value. In one embodiment, after the step S204b, the second decoding unit 114b decodes the detected data content for locating the errors, as shown in step S206b. In step S208b, the second error correction module 116b corrects the errors based on the second coding mode.

The time of locating the errors of the data content based on the first coding mode is greater than the time of locating the errors of the data content based on the second coding mode.

In one embodiment, a first correction unit of the first coding mode is different from a second correction unit of the second coding mode. For example, the first correction unit of the first coding mode is greater than the second correction unit of the second coding mode.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A dual mode error correction code (ECC) apparatus for a flash memory, the dual mode ECC apparatus comprising:
a syndrome detection unit, detecting the data content of the flash memory for computing the amount of errors in the data content to determine whether the amount of the errors exceeds a pre-determined threshold value;
a first ECC unit, correcting the errors in the data content based on a first coding mode;
a second ECC unit, correcting the errors in the data content based on a second coding mode; and
a switch module coupling the syndrome detection unit to the first ECC unit and the second ECC unit, respectively, either switching to the first ECC unit for activating the first coding mode of the first ECC unit if the amount of the errors is fewer than a pre-determined threshold value or switching to the second ECC unit for activating the second coding mode of the second ECC unit if the amount of the errors is greater than the pre-determined threshold value.

2. The dual mode ECC apparatus of claim 1, wherein the first ECC unit further comprises:
a first decoding unit coupled to the switch module, decoding the detected data content from the syndrome detection unit for locating the errors therein; and
a first error correction module coupled to the first decoding unit, correcting the located errors in the data content based on the first coding mode.

3. The dual mode ECC apparatus of claim 2, wherein the first coding mode performed by the first decoding unit comprises a RS algorithm.

4. The dual mode ECC apparatus of claim 2, wherein the second ECC unit further comprises:
a second decoding unit coupled to the switch module, decoding the detected data content from the syndrome detection unit for locating the errors therein; and
a second error correction module coupled to the second decoding unit, correcting the located errors in the data content based on the second coding mode.

5. The dual mode ECC apparatus of claim 4, wherein the second coding mode performed by the second decoding unit comprises a BCH algorithm.

6. The dual mode ECC apparatus of claim 4, wherein the time of locating the errors of the data content in the first error correction module is greater than the time of locating the errors of the data content in the second error correction module.

7. The dual mode ECC apparatus of claim 1, wherein the syndrome detection unit is performed by RS algorithm.

8. The dual mode ECC apparatus of claim 1, wherein the syndrome detection unit is performed according to BCH algorithm.

9. The dual mode ECC apparatus of claim 1, wherein a first correction unit of the first coding mode is different from a second correction unit of the second coding mode.

10. The dual mode ECC apparatus of claim 9, wherein the first correction unit of the first coding mode is greater than the second correction unit of the second coding mode.

11. A method of performing dual mode error correction code (ECC) apparatus for a flash memory, the method comprising the steps of:
receiving data content from the flash memory;
detecting the data content for computing the amount of errors in the data content to determine whether the amount of the errors exceeds a pre-determined threshold value;
switching to a first coding mode of a first ECC unit for activating the first coding mode and correcting the errors based on the first coding mode if the amount of the errors is fewer than a pre-determined threshold value; and
switching to a second coding mode of a second ECC unit for activating the second coding mode and correcting the errors based on the second coding mode if the amount of the errors is greater than the pre-determined threshold value.

12. The method of claim 11, during the step of switching to the first coding mode of the first ECC unit for activating the first coding mode and correcting the errors based on the first coding mode if the amount of the errors is fewer than the pre-determined threshold value, further comprising a step of decoding the detected data content for locating the errors.

13. The method of claim 12, wherein the first coding mode performed by the first decoding unit comprises a RS algorithm.

14. The method of claim 11, during the step of switching to a second coding mode of a second ECC unit for activating the second coding mode and correcting the errors based on the second coding mode if the amount of the errors is greater than the pre-determined threshold value, further comprising a step of decoding the detected data content for locating the errors.

15. The method of claim 14, wherein the second coding mode performed by the second decoding unit comprises a BCH algorithm.

16. The method of claim 14, wherein the time of locating the errors of the data content based on the first coding mode is greater than the time of locating the errors of the data content based on the second coding mode.

17. The method of claim 11, wherein the step of detecting the data content is performed by a RS algorithm.

18. The method of claim 11, wherein the step of detecting the data content is performed by a BCH algorithm.

19. The method of claim 11, wherein a first correction unit of the first coding mode is different from a second correction unit of the second coding mode.

20. The method of claim 19, wherein the first correction unit of the first coding mode is greater than the second correction unit of the second coding mode.
